(19) United States
(12) Patent Application Publication
(10) Pub. No.: US 2013/0208205 A1
(43) Pub. Date: Aug. 15, 2013

(54) THIN FILM TRANSISTOR SUBSTRATE

(71) Applicant: Katsunori Misaki, Yonago-shi (JP)

(72) Inventor: Katsunori Misaki, Yonago-shi (JP)

(73) Assignee: Sharp Kabushiki Kaisha, Osaka-shi (JP)

(21) Appl. No.: 13/813,703

(22) PCT Filed: May 26, 2011
(86) PCT No.: PCT/JP2011/002931

§ 371 Date: Feb. 22, 2013

(30) Foreign Application Priority Data
Aug. 3, 2010 (JP) 2010-174792

(51) Int. Cl. H01L 33/00; G02F 1/136

(52) U.S. Cl. CPC H01L 33/0041; G02F 1/136
USPC 349/43; 257/79; 438/22

(57) ABSTRACT

It is an objective of the present invention to provide a thin film transistor substrate in which satisfactory contact between a drain electrode and a pixel electrode is achieved.

A drain electrode (25d) includes a first conductive film (25dp), and a second conductive film (25dq) made of aluminum and stacked on the first conductive film (25dp). The second conductive film (25dq) is spaced apart from a first contact hole (27a) by a cavity section (28a) formed between the second conductive film (25dq) and the first contact hole (27a), where the cavity section (28a) is in communication with the first contact hole (27a). A pixel electrode (29) is provided to be out of contact with the second conductive film (25dq) of the drain electrode (25d).

### TECHNICAL FIELD

The present invention relates to thin film transistors, to liquid crystal display devices including the thin film transistors, and to methods for fabricating thin film transistor substrates, and specifically to a thin film transistor substrate including a thin film transistor having a semiconductor layer made of an oxide semiconductor, to a liquid crystal display device, and to a method for fabricating a thin film transistor substrate.

### BACKGROUND ART

In thin film transistor substrates included in liquid crystal display devices, thin film transistors (hereinafter also referred to as “TFTs”) are used as switching elements of pixels each of which is the smallest unit of an image. Conventionally, TFTs whose semiconductor layers are made of amorphous silicon have been used. However, in recent years, instead of the TFTs including the semiconductor layers made of amorphous silicon, TFTs including semiconductor layers made of an oxide semiconductor have been proposed. The TFTs including oxide semiconductor layers exhibit satisfactory characteristics such as high mobility, high reliability, and a low off current, and thus have been actively researched and developed.

A TFT having a bottom gate structure generally includes a gate electrode provided on a glass substrate, a gate insulating film provided to cover the gate electrode, a semiconductor layer provided on the gate insulating film to overlap the gate electrode, and a source electrode and a drain electrode which are provided on the gate insulating film to be spaced apart from each other and to overlap the semiconductor layer, wherein a channel section is formed in a portion of the semiconductor layer exposed between the source electrode and the drain electrode. The TFT is covered with an interlayer insulating film provided on the source electrode and the drain electrode. A contact hole extending to the drain electrode is formed in the interlayer insulating film, and an inner surface of the contact hole is covered with a pixel electrode made of a transparent conductive film, thereby electrically connecting the pixel electrode to the drain electrode.

Here, the drain electrode generally has a configuration in which a plurality of metal thin films are stacked. An example of a layered structure of the drain electrode includes a configuration in which a first conductive film made of a titanium film, a second conductive film made of an aluminum film, and a third conductive film made of a molybdenum nitride film are sequentially stacked on the gate insulating film.

In etching to form the contact hole, the contact hole is formed to extend from a surface of the interlayer insulating film to the drain electrode. The etching is performed, for example, by dry etching using a fluorine-based gas as an etching gas. Here, when the contact hole is extended to the drain electrode by the etching gas, and the contact hole passes through the third conductive film, the second conductive film (the aluminum film) is exposed in the contact hole.

When the aluminum film exposed in the contact hole is brought into contact with the etching gas, an aluminum fluoride film is formed on a surface of the aluminum film. Aluminum fluoride has high resistance, and thus the surface of the aluminum film is covered with a high-resistance coating. Moreover, when a resist is removed by oxygen ashing, a surface of the aluminum fluoride film is oxidized, which results in that the surface of the aluminum film is covered with an aluminum oxide film containing fluorine (that is, a passivation coating).

Thus, when an ITO film, or the like is provided as the pixel electrode on the inner surface of the contact hole, the ITO film is in contact with the drain electrode, but part of the drain electrode at which the drain electrode is in contact with the pixel electrode is covered with the high-resistance coating made of aluminum fluoride and the passivation coating made of aluminum oxide. Thus, defective conduction may be caused, which may result in quality degradation.

Patent Document 1 discloses an active matrix substrate in which a source electrode and a drain electrode are formed to have a multilayer structure composed of a low-resistance metal layer and a heat-resistant metal layer removable by an etching gas of a gate insulating layer, a means to protect at least a channel section of an insulated gate transistor and a signal line is provided, an opening in an insulating layer as well as in the gate insulating layer is formed by using a photosensitive resin pattern whose cross section has an inverse tapered shape, the low-resistance metal layer exposed in the opening is removed, and then a conductive thin film layer for a pixel electrode is lifted off by using the photosensitive resin pattern as a lift-off agent, thereby forming the pixel electrode.

### CITATION LIST

### Patent Document

PATENT DOCUMENT 1: Japanese Patent Publication No. 2006-301560

### SUMMARY OF THE INVENTION

### Technical Problem

However, when an active matrix substrate is formed according to the method disclosed in Patent Document 1, the gate insulating layer disposed under the drain electrode is side-etched in forming a contact hole, so that an eave shape may be formed. Moreover, when the gate insulating layer is side-etched, defective conduction may be caused between the drain electrode and the pixel electrode due to step-caused disconnection.

It is an objective of the present invention to provide a thin film transistor substrate in which satisfactory contact between a drain electrode and a pixel electrode is achieved.

### Solution to the Problem

A thin film transistor substrate of the present invention includes:

a substrate;

a thin film transistor including
a gate electrode provided on the substrate,
a gate insulating film provided to cover the gate electrode,
an oxide semiconductor film provided on the gate insulating film and including a channel section formed at a position facing the gate electrode, and
a source electrode and a drain electrode provided on the oxide semiconductor film to be spaced apart from each other with the channel section sandwiched therebetween;

an interlayer insulating film which is provided above the gate insulating film to cover the thin film transistor and in which a first contact hole extending to the drain electrode is formed; and

a pixel electrode provided on the interlayer insulating film and electrically connected to the drain electrode via the first contact hole, wherein

the drain electrode includes a first conductive film and a second conductive film which is made of aluminum and is stacked on the first conductive film, and the second conductive film and the first contact hole are spaced apart from each other with a cavity section formed therebetween, where the cavity section is in communication with the first contact hole, and

the pixel electrode is provided to be out of contact with the second conductive film of the drain electrode.

With this configuration, a high-resistance coating, a passivation coating, etc. do not exist on a surface of the drain electrode, and the pixel electrode is in contact with the drain electrode at a portion other than the second conductive film (that is, at the first conductive film, etc.), so that the pixel electrode is electrically connected to the drain electrode. Thus, a contact failure between the pixel electrode and the drain electrode due to the existence of the high-resistance coating, the passivation coating, etc. on the surface of the drain electrode is not caused, and thus satisfactory contact between the pixel electrode and the drain electrode can be achieved.

Moreover, the second conductive film and the first contact hole are spaced apart from each other with the cavity section formed therebetween, where the cavity section is in communication with the first contact hole. Thus, the second conductive film made of an aluminum film is out of contact with the pixel electrode made of an ITO film, or the like. Thus, there is no risk of degradation in conductive performance resulting from deterioration of the aluminum film caused by bringing the aluminum film into contact with the ITO film, etc.

Preferably, the thin film transistor substrate of the present invention further includes:

an auxiliary capacitor element including
a lower electrode provided on the substrate in a same layer as the gate electrode,
the gate insulating film provided to cover the gate electrode and the lower electrode,
an etch stopper layer made of an oxide semiconductor provided on the gate insulating film at a position facing the lower electrode, and
an upper electrode provided on the etch stopper layer in a same layer as the drain electrode, wherein

the auxiliary capacitor element is covered with the interlayer insulating film in which a second contact hole extending to the etch stopper layer and the upper electrode is further formed,

the upper electrode includes a first conductive film and a second conductive film which is made of aluminum and is stacked on the first conductive film, and the second conductive film and the second contact hole are spaced apart from each other with a cavity section formed therebetween, where the cavity section is in communication with the second contact hole, and

the pixel electrode is provided on an inner surface of the second contact hole to be electrically connected to the upper electrode without contacting the second conductive film of the upper electrode.

With this configuration, a high-resistance coating, a passivation coating, etc. do not exist on a surface of the upper electrode, and the pixel electrode is in contact with the upper electrode at a portion other than the second conductive film (that is, at the first conductive film, etc.), so that the pixel electrode is electrically connected to the upper electrode. Thus, a contact failure between the pixel electrode and the upper electrode due to the existence of the high-resistance coating, the passivation coating, etc. on the surface of the upper electrode is not caused, and thus satisfactory contact between the pixel electrode and the upper electrode can be achieved.

Moreover, the second conductive film and the second contact hole are spaced apart from each other with the cavity section formed therebetween, where the cavity section is in communication with the second contact hole. Thus, the second conductive film made of an aluminum film is out of contact with the pixel electrode made of an ITO film, or the like. Thus, there is no risk of degradation in conductive performance resulting from deterioration of the aluminum film caused by bringing the aluminum film into contact with the ITO film, etc.

In the thin film transistor substrate of the present invention, the first conductive film may be made of a refractory metal film. Examples of the refractory metal film include metal films such as a titanium (Ti) film, a molybdenum (Mo) film, a tantalum (Ta) film, a tungsten (W) film, a chromium (Cr) film, and a nickel (Ni) film, metal films made of alloys of these metals, etc.

In the thin film transistor substrate of the present invention, the drain electrode may further include a third conductive film provided on the second conductive film in addition to the first conductive film and the second conductive film.

Alternatively, in the thin film transistor substrate of the present invention,

the drain electrode further may include a third conductive film provided on the second conductive film in addition to the first conductive film and the second conductive film, and

the upper electrode further may include a third conductive film provided on the second conductive film in addition to the first conductive film and the second conductive film.

The thin film transistor substrate of the present invention is preferably used in a liquid crystal display device including: the thin film transistor substrate;

a counter substrate disposed to face the thin film transistor substrate; and

a liquid crystal layer provided between the thin film transistor substrate and the counter substrate.

A method for fabricating the thin film transistor substrate of the present invention includes:

a thin film transistor formation step of forming the thin film transistor including
the gate electrode provided on the substrate, and
the gate insulating film provided to cover the gate electrode,
the oxide semiconductor film provided on the gate insulating film and including the channel section formed at a position facing the gate electrode, and
the source electrode and the drain electrode provided on the oxide semiconductor film to be spaced apart from each other with the channel section sandwiched therebetween, where each of the source electrode and the drain electrode includes the first conductive film and the second conductive film stacked on the first conductive film;

an interlayer insulating film formation step of forming the interlayer insulating film above the gate insulating film to cover the thin film transistor formed in the thin film transistor formation step;

a first etching step of performing, after the interlayer insulating film formation step, dry etching on the interlayer insulating film to form the first contact hole extending from the interlayer insulating film to the drain electrode to expose the second conductive film in the first contact hole;

a second etching step of performing wet etching on the first contact hole, which has been formed in the first etching step, by using an etchant having a high selectivity ratio with respect to an aluminum-oxide semiconductor to form a cavity section between the second conductive film and the first contact hole to allow the second conductive film to be spaced apart from the first contact hole, where the cavity section is in communication with the first contact hole; and

a pixel electrode formation step of forming, after the cavity section is formed in the second etching step, a conductive film in a region including a surface of the interlayer insulating film and an inner surface of the first contact hole to from the pixel electrode which is electrically connected to the drain electrode without contacting the second conductive film of the drain electrode.

With this method, after the first contact hole is formed in the first etching step, a high-resistance coating made of aluminum fluoride, and in some cases, a passivation coating made of aluminum oxide are formed on a surface of an aluminum film which is the second conductive film. However, in the second etching step, wet etching using an etchant having a high selectivity ratio with respect to the aluminum-oxide semiconductor is performed to form a cavity section between the second conductive film and the first contact hole to allow the second conductive film to be spaced apart from the first contact hole, where the cavity section is in communication with the first contact hole. Thus, the high-resistance coating, the passivation coating, etc., which has been formed in the first etching step, are removed in the second etching step. Thus, the pixel electrode formed in the pixel electrode formation step is in contact with the drain electrode at a portion other than the second conductive film (that is, at the first conductive film, etc.), so that the pixel electrode is electrically connected to the drain electrode. Thus, a contact failure between the pixel electrode and the drain electrode due to the existence of the high-resistance coating, the passivation coating, etc. on the surface of the drain electrode is not caused, and thus satisfactory contact between the pixel electrode and the drain electrode can be achieved.

In the method for fabricating the thin film transistor substrate of the present invention, the etchant used in the second etching step is preferably ammonia water.

### Advantages of the Invention

According to the present invention, after the first contact hole is formed, a high-resistance coating made of aluminum fluoride, a passivation coating made of aluminum oxide containing fluorine, etc. are formed on a surface of an aluminum film which is the second conductive film. However, in a succeeding step, a cavity section which is in communication with the first contact hole is formed between the second conductive film and the first contact hole to allow the second conductive film to be spaced apart from the first contact hole, thereby removing the high-resistance coating, the passivation coating, etc. Thus, the pixel electrode is in contact with the drain electrode at a portion other than the second conductive film (that is, at the first conductive film, etc.), so that the pixel electrode is electrically connected to the drain electrode. Thus, the pixel electrode is in contact with the drain electrode at a portion other than the second conductive film (that is, at the first conductive film, etc.), so that the pixel electrode is electrically connected to the drain electrode. Thus, a contact failure between the pixel electrode and the drain electrode due to the existence of the high-resistance coating, the passivation coating, etc. on the surface of the drain electrode is not caused, and thus satisfactory contact between the pixel electrode and the drain electrode can be achieved.

### BRIEF DESCRIPTION OF THE DRAWINGS

FIG. 1 is a plan view schematically illustrating a liquid crystal display device of the present embodiment.

FIG. 2 is a cross-sectional view along the line II-II of FIG. 1.

FIG. 3 is a plan view illustrating a substantial portion of the thin film transistor substrate according to the present embodiment in an enlarged manner.

FIG. 4 is a cross-sectional view along the line A-A of FIG. 3.

FIG. 5 is a cross-sectional view along the line B-B of FIG. 3.

FIG. 6 is a cross-sectional view along the line C-C of FIG. 3.

FIGS. 7A-7C are views illustrating a method for fabricating the thin film transistor substrate of the present embodiment, wherein FIG. 7A is a cross-sectional view along the line A-A of FIG. 3, FIG. 7B is a cross-sectional view along the line B-B of FIG. 3, and FIG. 7C is a cross-sectional view along the line C-C of FIG. 3.

FIGS. 8A-8C are views illustrating a process step in the method for fabricating the thin film transistor substrate following the process step of FIGS. 7A-7C.

FIGS. 9A-9C are views illustrating a process step in the method for fabricating the thin film transistor substrate following the process step of FIGS. 8A-8C.

FIGS. 10A-10C are views illustrating a process step in the method for fabricating the thin film transistor substrate following the process step of FIGS. 9A-9C.

FIGS. 11A-11C are views illustrating a process step in the method for fabricating the thin film transistor substrate following the process step of FIGS. 10A-10C.

FIGS. 12A-12C are views illustrating a process step in the method for fabricating the thin film transistor substrate following the process step of FIGS. 11A-11C.

FIGS. 13A-13C are views illustrating a process step in the method for fabricating the thin film transistor substrate following the process step of FIGS. 12A-12C.

FIGS. 14A-14C are views illustrating a process step in the method for fabricating the thin film transistor substrate following the process step of FIGS. 13A-13C.

### DESCRIPTION OF EMBODIMENTS

Embodiments of the present invention will be described in detail below with reference to the drawings. The following embodiments are not intended to limit the present invention.

<Configuration of Liquid Crystal Display Device>

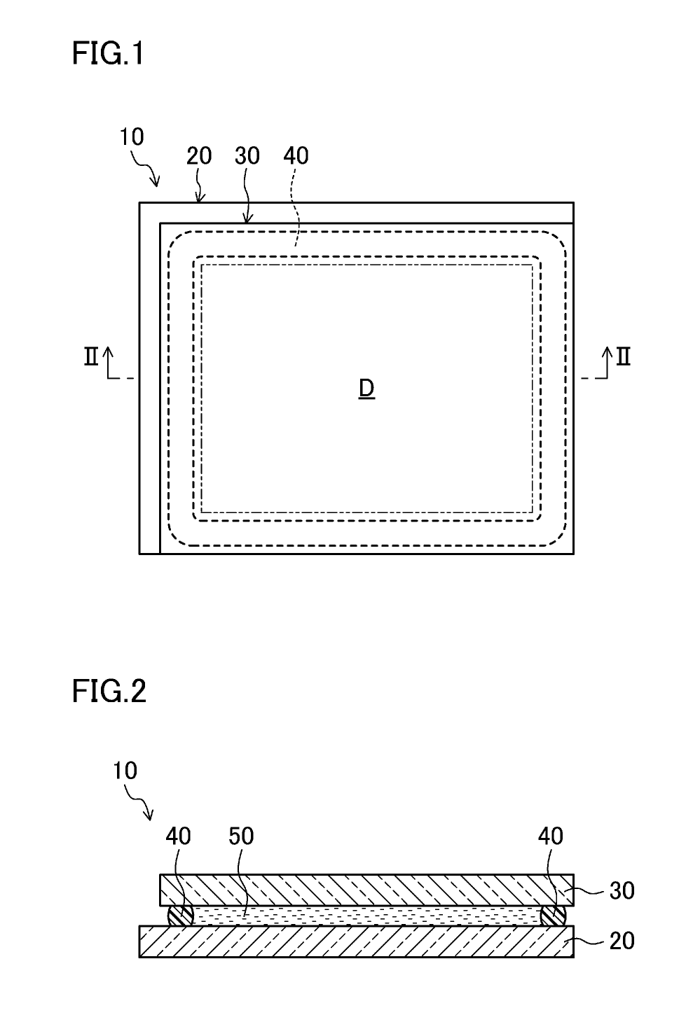

FIGS. 1 and 2 illustrate a liquid crystal display device 10 according to the present embodiment. The liquid crystal display device 10 includes a TFT substrate 20 and a counter substrate 30 which are arranged to face each other. The substrates 20 and 30 are adhered to each other by a sealing material 40 arranged to have a frame-like shape at outer peripheral parts of the substrates 20 and 30. In the space surrounded by the sealing material 40 between the substrates 20 and 30, a liquid crystal layer 50 is provided as a display layer. The liquid crystal display device 10 has a display region D which is surrounded by the sealing material 40 and in which a plurality of pixels are arranged in a matrix pattern. A region by which the display region D is surrounded is a picture-frame region F.

(TFT Substrate)

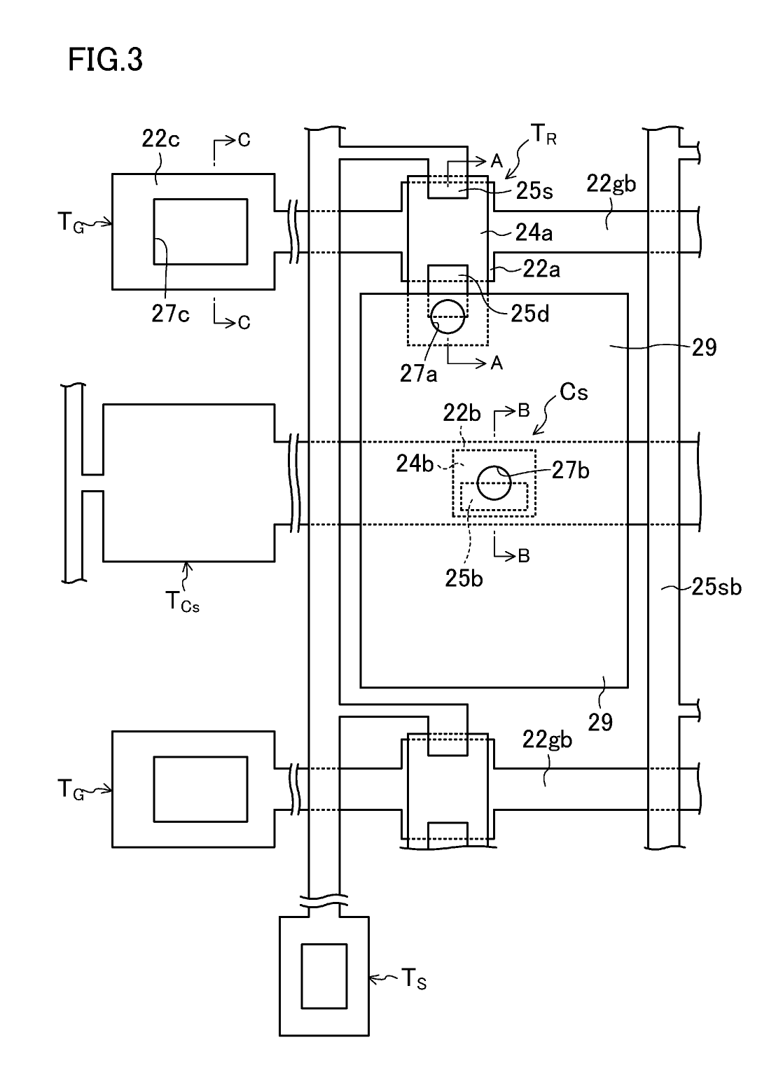

FIG. 3 is a plan view illustrating the TFT substrate 20. The TFT substrate 20 is formed by stacking, on a substrate 21 made of, for example, a glass substrate, a first metal of which a gate electrode 22a, a lower electrode 22b, a terminal 22c, a gate line 22gb, transfer pads (not shown), etc. are made; a gate insulating film 23 made of SiO₂, a multilayer structure of SiO₂ and SiN, or the like; oxide semiconductor films 24a, 24b made of an IGZO film, or the like; a second metal of which a source electrode 25s, a drain electrode 25d, an upper electrode 25b, a source line 25sb, etc. are made; an interlayer insulating film 26 made of SiO₂, SiN, a transparent insulating resin, or the like; a pixel electrode 29 made of an indium tin oxide (ITO) film, or the like; and an alignment layer (not shown) made of a polyimide film, or the like.

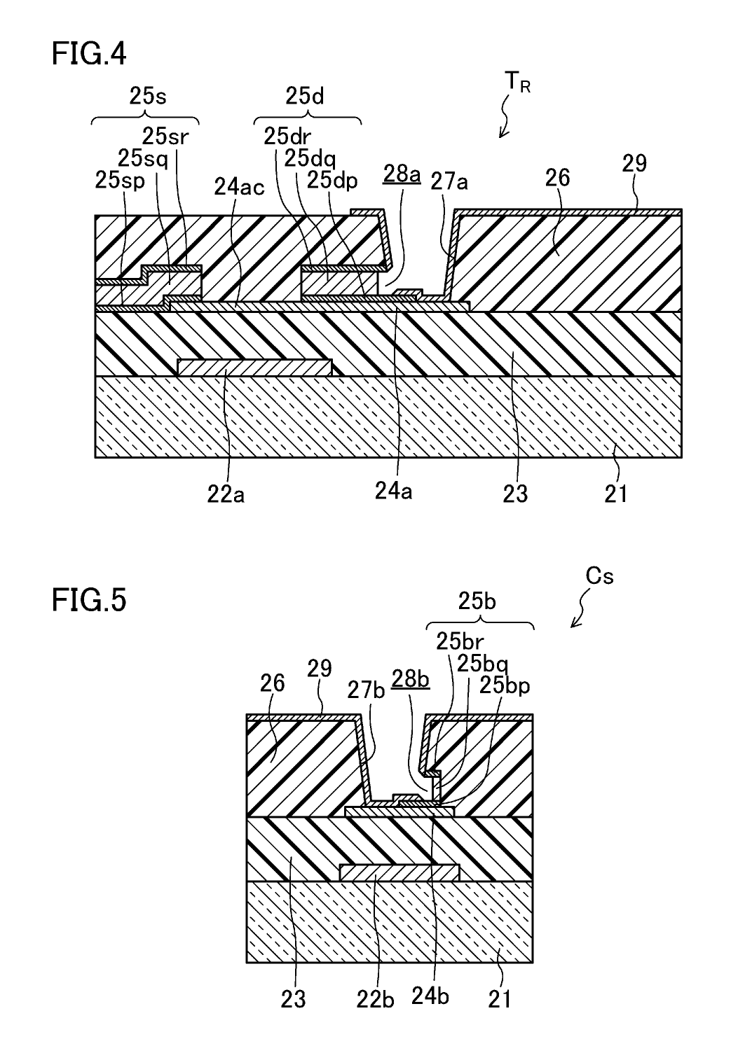

FIG. 4 is a cross-sectional view along the line A-A of FIG. 3.

As illustrated in FIG. 4, the gate electrode 22a is covered with the gate insulating film 23, and on the gate insulating film 23, the oxide semiconductor film 24a including a channel section 24ac formed at a position facing the gate electrode 22a is provided, and on the oxide semiconductor film 24a, the source electrode 25s and the drain electrode 25d are provided to be spaced apart from each other with the channel section 24ac sandwiched therebetween. These components are included in a thin film transistor T_{R}.

The gate electrode 22a is made of the first metal, and includes for example, an aluminum film, a titanium film, and a titanium nitride film which are sequentially stacked from bottom to top.

The source electrode 25s and the drain electrode 25d are made of the second metal, and each include a first conductive film, a second conductive film stacked on the first conductive film, and a third conductive film stacked on the second conductive film. That is, the source electrode 25s has a configuration in which a first conductive film 25sp, a second conductive film 25sq, and a third conductive film 25sr are sequentially stacked, and the drain electrode 25d has a configuration in which a first conductive film 25dp, a second conductive film 25dq, and a third conductive film 25dr are sequentially stacked. The first conductive film 25sp, 25dp is made of, for example, a titanium (Ti) film, and has a thickness of, for example, 50 nm. The second conductive film 25sq, 25dq is made of, for example, an aluminum film, and has a thickness of, for example, 100 nm. The third conductive film 25sr, 25dr is made of, for example, a refractory metal film such as a molybdenum nitride (MoN) film, and has a thickness of, for example, 150 nm. Note that the first conductive film 25sp, 25dp and the third conductive film 25sr, 25dr are not limited to the metal films described above, but the first conductive film 25sp, 25dp is preferably a refractory metal film. Examples of the first conductive film 25sp, 25dp include the titanium (Ti) film, and additionally, metal films such as a molybdenum (Mo) film, a tantalum (Ta) film, a tungsten (W) film, a chromium (Cr) film, and a nickel (Ni) film, metal films made of alloys of these metals, etc.

A first contact hole 27a is formed in the interlayer insulating film 26, and extends from a surface of the interlayer insulating film 26 to the drain electrode 25d. An inner surface of the first contact hole 27a is covered with the pixel electrode 29, and the pixel electrode 29 is electrically connected to the drain electrode 25d.

The pixel electrode 29 is provided to be in contact with the first conductive film 25dp and the third conductive film 25dr of the drain electrode 25d. On the other hand, the pixel electrode 29 is not in contact with the second conductive film 25dq of the drain electrode 25d. This is because between the first conductive film 25dp and the third conductive film 25dr, a cavity section 28a is formed in a wall of the first contact hole 27a so that the cavity section 28a is in communication with the first contact hole 27a, and thus the second conductive film 25dq of the drain electrode 25d is spaced apart from the first contact hole 27a. The cavity section 28a is formed as a cavity having a depth of about 50-200 nm from the wall of the first contact hole 27a.

If the aluminum film which is the second conductive film 25dq and the ITO film which is the pixel electrode 29 are in contact with each other, a surface of the aluminum film is covered with aluminum oxide due to oxidization of the aluminum film, and simultaneously, the ITO film is reduced to be an indium-rich film. This causes a problem where conductive performance is degraded because the surface of the aluminum film is covered with the aluminum oxide. However, the pixel electrode 29 is disposed so as not to contact the second conductive film 25dq, and thus the problem described above does not arise.

FIG. 5 is a cross-sectional view along the line B-B of FIG. 3.

As illustrated in FIG. 5, the lower electrode 22b is covered with the gate insulating film 23, and on the gate insulating film 23, an etch stopper layer 24b is provided at a position facing the lower electrode 22b, and on the etch stopper layer 24b, the upper electrode 25b is provided. These components are included in an auxiliary capacitor element Cs.

The lower electrode 22b is made of the first metal, and includes, for example, an aluminum film, a titanium film, and a titanium nitride film which are sequentially stacked from bottom to top. Note that the lower electrode 22b is connected to an auxiliary capacitor terminal T_{Cs} provided in a terminal region T.

The upper electrode 25b is made of the second metal, and includes a first conductive film 25bp, a second conductive film 25bq stacked on the first conductive film 25bp, and a third conductive film 25br stacked on the second conductive film 25bq. The first conductive film 25bp is made of, for example, a titanium (Ti) film, and has a thickness of, for example, 50 nm. The second conductive film 25bq is made of, for example, an aluminum film, and has a thickness of, for example, 100 nm. The third conductive film 25br is made of, for example, a refractory metal film such as a molybdenum nitride (MoN) film, and has a thickness of, for example, 150 nm. Note that the first conductive film 25bp and the third conductive film 25br are not limited to the metal films described above, but the first conductive film 25bp is preferably a refractory metal film. Examples of the first conductive film 25bp include the titanium (Ti) film, and additionally, metal films such as a molybdenum (Mo) film, a tantalum (Ta) film, a tungsten (W) film, a chromium (Cr) film, and a nickel (Ni) film, metal films made of alloys of these metals, etc.

A second contact hole 27b is formed in the interlayer insulating film 26, and extends from the surface of the interlayer insulating film 26 to the upper electrode 25b. An inner surface of the second contact hole 27b is covered with the pixel electrode 29, and the pixel electrode 29 is electrically connected to the upper electrode 25b.

The pixel electrode 29 is provided to be in contact with the first conductive film 25bp and the third conductive film 25br of the upper electrode 25b. On the other hand, the pixel electrode 29 is not in contact with the second conductive film 25bq of the upper electrode 25b. This is because between the first conductive film 25bp and the third conductive film 25br, a cavity section 28b is formed in a wall of the second contact hole 27b so that the cavity section 28b is in communication with the second contact hole 27b, and thus the second conductive film 25bq of the upper electrode 25b is spaced apart from the second contact hole 27b. The cavity section 28b is formed as a cavity having a depth of about 50-200 nm from the wall of the second contact hole 27b.

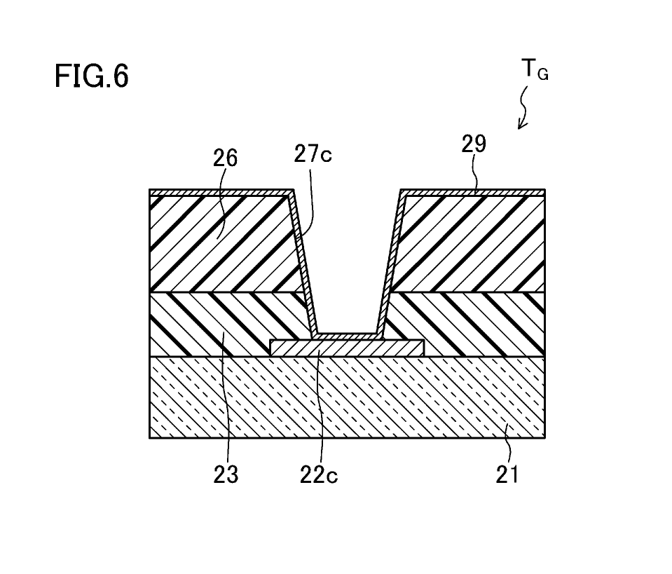

FIG. 6 is a cross-sectional view along the line C-C of FIG. 3.

As illustrated in FIG. 6, the terminal 22c is covered with the gate insulating film 23 and the interlayer insulating film 26. The terminal 22c is made of the first metal, and includes, for example, an aluminum film, a titanium film, and a titanium nitride film which are sequentially stacked from bottom to top.

A third contact hole 27c is formed in the gate insulating film 23 and the interlayer insulating film 26 to extend from the surface of the protective film 26 to the terminal 22c. An inner surface of the third contact hole 27c is covered with the pixel electrode 29, and the pixel electrode 29 is electrically connected to the terminal 22c, thereby forming a gate terminal section T_{G}.

Note that FIG. 6 illustrates a cross section of the gate terminal section T_{G}, but a source terminal section T_{S} also has a similar cross-sectional structure.

The TFT substrate 20 is formed such that part of the picture-frame region of the TFT substrate 20 protrudes beyond the counter substrate 30, thereby forming the terminal region T to which external connection terminals (not shown) of mounted components, etc. are attached. In the picture-frame region F, the transfer pads (not shown) via which a common potential is applied to a common electrode of the counter substrate 30 are formed, and each transfer pad is connected to a transfer bus line (not shown) arranged in the terminal region T.

A polarizing plate (not shown) is provided on a surface of the TFT substrate 20 opposite to the liquid crystal layer 50.

(Counter Substrate)

Although not illustrated, on a surface of a substrate body of the counter substrate 30, each of colored layers including red, green, and blue layers 22R, 22G, 22B are provided to a different pixel in the display region D. Moreover, the common electrode, which has a thickness of, for example, 100 nm, and is made of ITO, or the like, is provided above the colored layers 22R, 22G, 22B. Further, an alignment layer is formed to cover the common electrode. The colored layers described above include three types of layers, that is, the red, green, and blue layers. However, the colored layers are not limited to these layers, but may include, for example, four types of layers: red, green, blue, and yellow layers.

Note that a polarizing plate (not shown) is provided on a surface of the counter substrate 30 opposite to the liquid crystal layer 50.

(Sealing Material)

At the outer peripheral parts of the TFT substrate 20 and the counter substrate 30, the sealing material 40 is provided to have the shape of a ring along the picture-frame region F. The TFT substrate 20 and the counter substrate 30 are adhered to each other by the sealing material 40.

The sealing material 40 is obtained by curing a starting material of the sealing material by heating or by ultraviolet irradiation, where the starting material contains an adhesive of a thermosetting resin, an ultraviolet curable resin, etc. having flowability (e.g., an acryl-based resin and an epoxy-based resin) as a main component. The sealing material 40 includes, for example, conductive beads mixed therewith, and serves as a medium by which the common electrode is electrically connected to the transfer pads.

(Liquid Crystal Layer)

The liquid crystal layer 50 is made of, for example, a nematic liquid crystal material having electro-optic characteristics.

The liquid crystal display device 10 having the above-described configuration is configured such that each of pixel electrodes forms a pixel, and in each pixel, when the thin film transistor T_{R} is turned on by a gate signal sent via the gate line, a source signal is sent via the source line, so that a predetermined charge is applied to the pixel electrode via the source electrode and the drain electrode, which causes a potential difference between the pixel electrode and the common electrode of the counter substrate 30, thereby applying a predetermined voltage to a liquid crystal capacitor including the liquid crystal layer 50. The liquid crystal display device 10 displays an image by adjusting transmittance of light coming from the outside, based on the phenomenon that the alignment of liquid crystal molecules changes according to the magnitude of the applied voltage.

In the above description, the second metal, of which the source electrode 25s, the drain electrode 25d, the upper electrode 25b, and the like of the TFT substrate 20 are made, has a configuration in which the first conductive film 25sp, 25dp, 25bp, the second conductive film 25sq, 25dq, 25bq, and the third conductive film 25sr, 25dr, 25br are sequentially stacked. However, a configuration which does not include the third conductive film 25sr, 25dr, 25br (that is, a configuration in which two layers, the first conductive film 25sp, 25dp, 25bp and the second conductive film 25sq, 25dq, 25bq are stacked) may be possible.

<Method for Fabricating TFT Substrate>

A method for fabricating the TFT substrate 20 of the present embodiment will be described below. The method for fabricating the TFT substrate 20 of the present embodiment includes a thin film transistor formation step, an interlayer insulating film formation step, a first etching step, a second etching step, and a pixel electrode formation step.

(Thin Film Transistor Formation Step)

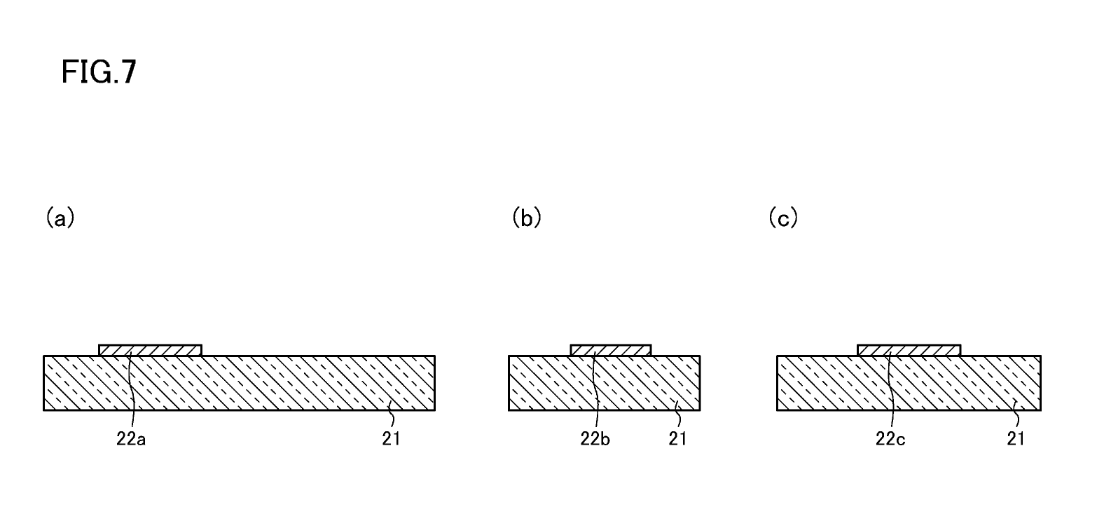

First, as illustrated in FIGS. 7A-7C, a first metal is provided on a substrate 21 to form a gate electrode 22a, a lower electrode 22b, a terminal 22c, a gate line 22gb (see FIG. 3), transfer pads (not shown), etc. Specifically, an aluminum film, a titanium film, and a titanium nitride film are successively formed by, for example, sputtering. Thereafter, photolithography is performed so that a resist pattern is left on portions which will be the gate electrode 22a, the lower electrode 22b, the terminal 22c, etc. Then, a multilayer structure which is a conductive film composed of the aluminum film, the titanium film, and the titanium nitride film is etched by, for example, dry etching (RIE) using a chlorine-based gas. After that, the resist is removed by a resist remover solution.

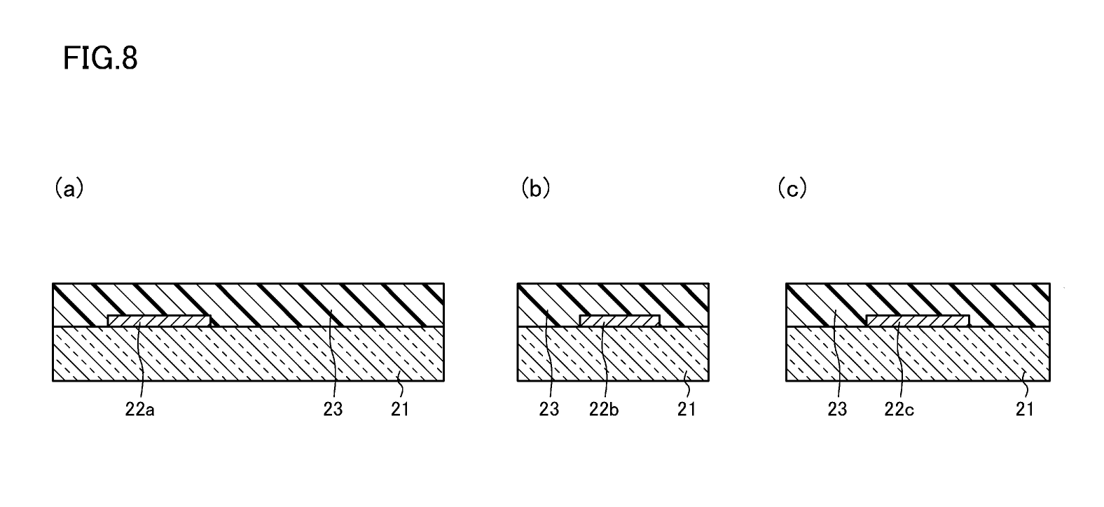

Next, as illustrated in FIGS. 8A-8C, a SiO₂ film is formed as a gate insulating film 23 by, for example, CVD.

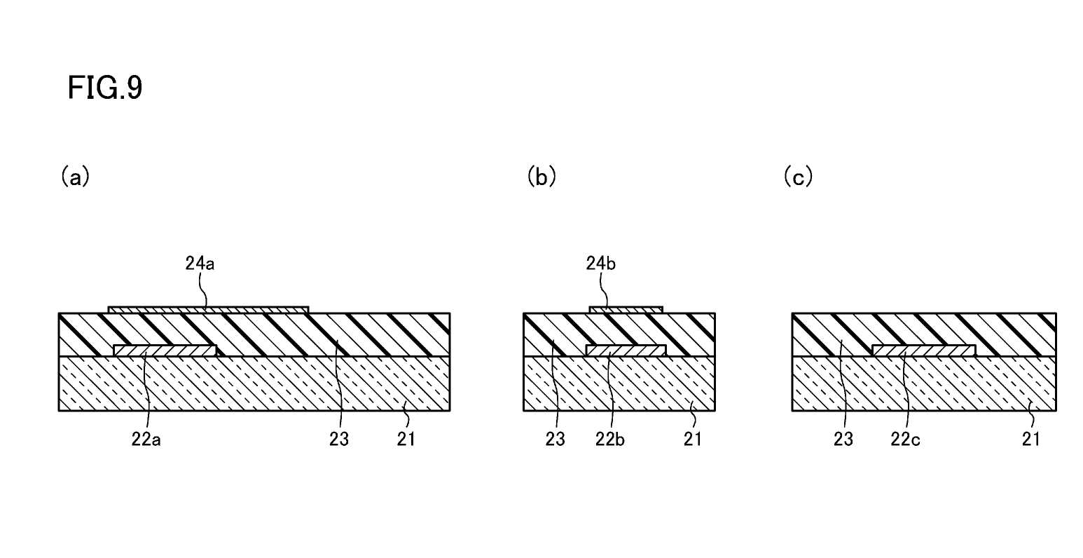

Next, as illustrated in FIGS. 9A-9C, an oxide semiconductor film 24a and an etch stopper layer 24b are formed. Specifically, an oxide semiconductor film such as an IGZO film is formed by, for example, sputtering, and then photolithography is performed so that a resist pattern is left on portions which will be the oxide semiconductor film 24a and the etch stopper layer 24b. Then, the IGZO film is etched by, for example, wet etching using an oxalic acid solution as an etchant. After that, the resist is removed by a resist remover solution.

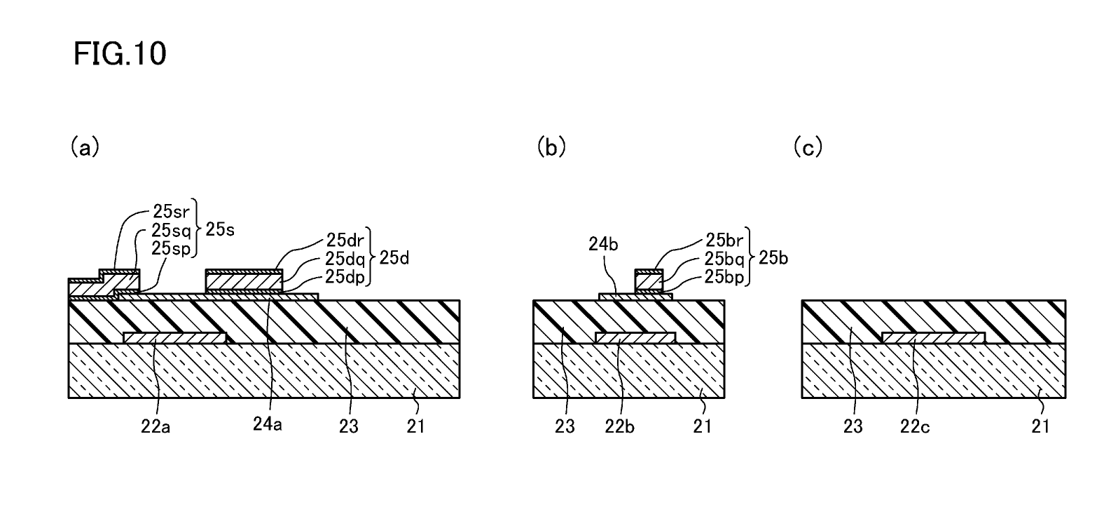

Subsequently, as illustrated in FIGS. 10A-10C, a source electrode 25s, a drain electrode 25d, and an upper electrode 25b are formed. Specifically, a titanium film (having a thickness of about 50 nm) which will be a first conductive film 25sp, 25dp, 25bp, an aluminum film (having a thickness of about 150 nm) which will be a second conductive film 25sq, 25dq, 25bq, and a molybdenum nitride film (having a thickness of about 100 nm) which will be a third conductive film 25sr, 25dr, 25br) are successively formed by, for example, sputtering. Then, photolithography is performed so that a resist pattern is left on portions which will be the source metal 25s, the drain electrode 25d, and the upper electrode 25b. Then, the second conductive film and the third conductive film are etched by, for example, wet etching using a mixed acid solution of phosphoric acid/acetic acid/nitric acid as an etchant. Further, the titanium film which is the first conductive film is etched by dry etching (RIE) using a chlorine-based gas. Thereafter, the resist is removed by a resist remover solution.

(Interlayer Insulating Film Formation Step)

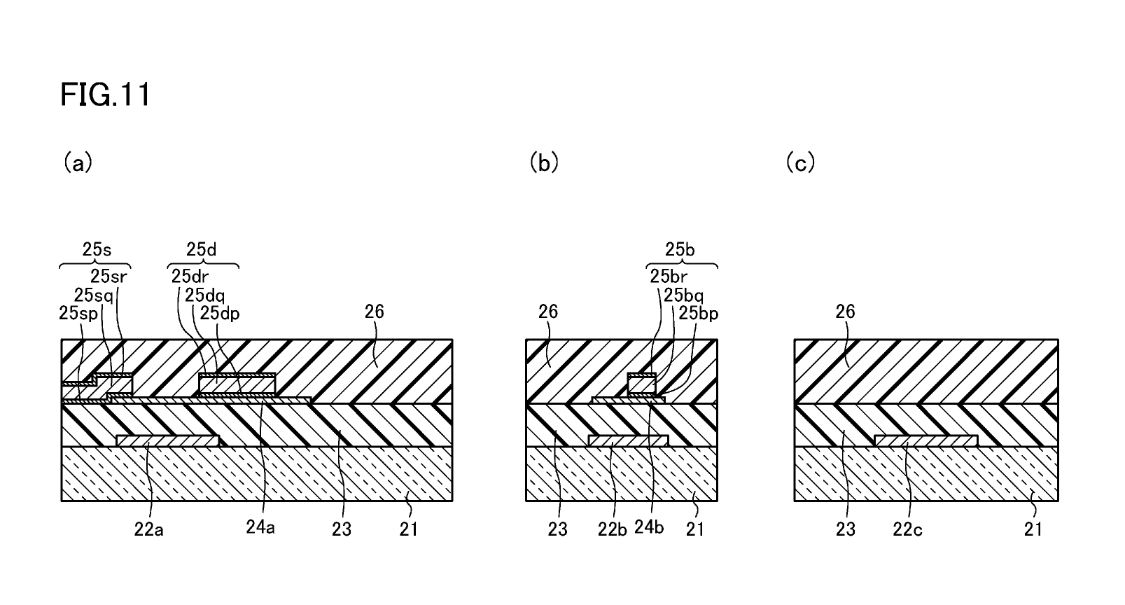

Next, as illustrated in FIGS. 11A-11C, a SiO₂ film is formed as an interlayer insulating film 26 by, for example, CVD.

(First Etching Step)

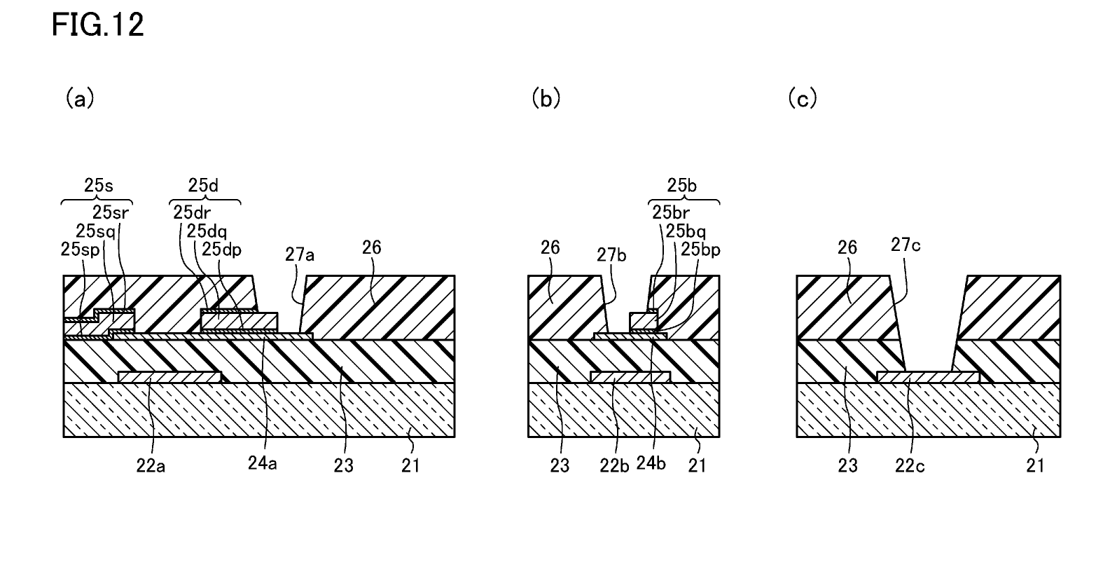

Then, the interlayer insulating film 26 is dry etched, thereby forming a first contact hole 27a, a second contact hole 27b, and a third contact hole 27c as illustrated in FIGS. 12A-12C.

Specifically, first, a photosensitive resist is applied to the interlayer insulating film 26. Then, photolithography is performed so that the resist is left on portions except portions which will be the first to third contact holes 27a-27c. Then, the interlayer dielectric film 26 is etched by dry etching (RIE) using, for example, a fluorine-based gas such as a sulfur hexafluoride (SF₆) gas, a carbon tetrafluoride (CF₄) gas, a trifluoromethane (CHF₃) gas, or the like, thereby forming the first to third contact holes 27a-27c.

Here, in a portion forming the thin film transistor T_{R}, as illustrated in FIG. 12A, the third conductive film 25dr which is an uppermost layer of the drain electrode 25d is also etched simultaneously with the interlayer insulating film 26. Moreover, the first contact hole 27a is formed in a region including an interface between the drain electrode 25d and the oxide semiconductor film 24a. That is, both the drain electrode 25d and the oxide semiconductor film 24a are exposed in the first contact hole 27a. Here, the oxide semiconductor film 24a is provided on part of a region which will be the first contact hole 27a, where the part is not provided with the drain electrode 25d. Thus, the oxide semiconductor film 24a serves as an etching stopper.

Moreover, here, in a manner similar to the portion forming the thin film transistor T_{R}, the third conductive film 25br which is the uppermost layer of the upper electrode 25b is also etched simultaneously with the interlayer insulating film 26 in a portion forming the auxiliary capacitor element Cs as illustrated in FIG. 12B. Moreover, the second contact hole 27b is formed in a region including an interface between the upper electrode 25b and the etch stopper layer 24b (that is, both the upper electrode 25b and the etch stopper layer 24b are exposed in the second contact hole 27b). Here, the etch stopper layer 24b is provided on part of the region which will be a second contact hole 27b, where the part is not provided with the upper electrode 25b. Thus, the etch stopper layer 24b serves as an etching stopper.

The first and second contact holes 27a, 27b are formed by removing the interlayer insulating film 26 and the third conductive films 25dr, 25br by etching, so that the second conductive films 25dq, 25bq are respectively exposed in the first and second contact holes 27a, 27b, and aluminum of the exposed surfaces of the second conductive films 25dq, 25bq is fluoridated by a fluorine-based gas, thereby forming high-resistance coatings made of aluminum fluoride on the surfaces of the second conductive films.

Subsequently to the etching, the resist is removed by oxygen ashing. Here, the second conductive films 25dq, 25bq, which are respectively exposed in the first and second contact holes 27a, 27b illustrated in FIGS. 12A, 12B, and thus are made of aluminum fluoride, are oxidized by oxygen ashing, thereby forming aluminum oxide films containing fluorine, that is, passivation coatings.

Note that as illustrated in FIG. 12C, in the gate terminal section T_{G}, the third contact hole 27c is formed, but in the etching, the interlayer insulating film 26 and the gate insulating film 23 are both removed, and the terminal 22c serves as an etch stopper.

(Second Etching Step)

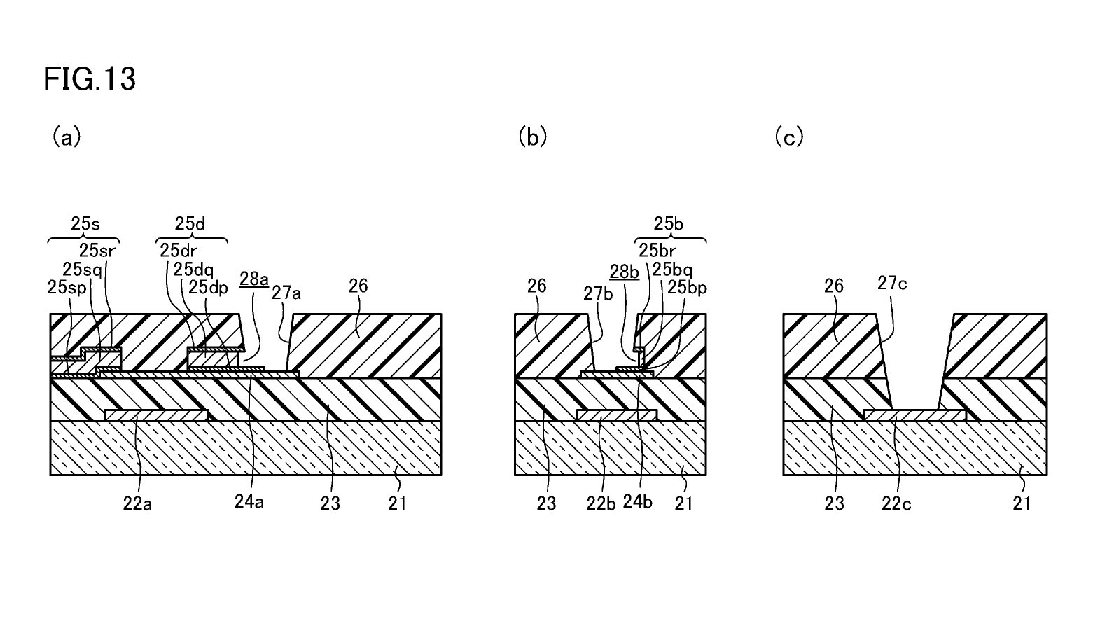

Subsequently to the first etching step, wet etching is performed as illustrated in FIGS. 13A and 13B. Here, as an etchant, for example, an etchant having a high selectivity ratio with respect to an aluminum-oxide semiconductor is used. Of films exposed in the first contact hole 27a and the second contact hole 27b, only the second conductive films 25dq, 25bq made of an aluminum film can thus be etched. Thus, the cavity sections 28a, 28b are formed. The selectivity ratio with respect to the aluminum-oxide semiconductor is preferably greater than or equal to 5. Examples of such etchant include ammonia water whose selectivity ratio with respect to the aluminum-oxide semiconductor is greater than or equal to 20.

Here, the surfaces of the second conductive films 25dq, 25bq are etched, so that the high-resistance coatings and the passivation coatings formed on the surfaces are removed. Thus, there is no risk of degradation in conductive performance due to the high-resistance coatings and the passivation coatings formed in the second conductive films 25dq, 25bq.

Note that as the etchant, for example, ammonia water, or the like, which is less likely to etch titanium, etc. is used. Thus, in the gate terminal section T_{G}, as illustrated in FIG. 13C, there is no risk of damage to the terminal 22c, and the like caused by the wet etching in the second etching step.

(Pixel Electrode Formation Step)

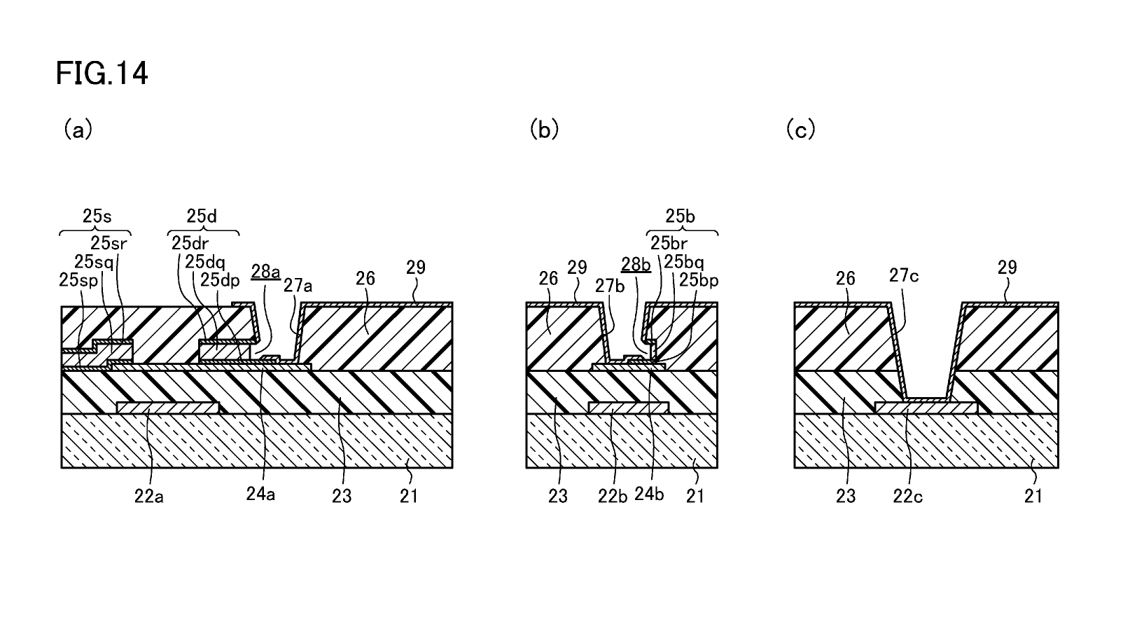

Finally, as illustrated in FIGS. 14A-14C, a pixel electrode 29 is formed.

Specifically, first, an ITO film is formed by, for example, sputtering. Then, photolithography is performed so that a resist pattern is left on a portion which will be the pixel electrode 29. Then, the ITO film is etched by using, for example, an oxalic acid solution as an etchant to remove the resist by a resist remover solution, thereby forming the pixel electrode.

Here, in the thin film transistor T_{R}, as illustrated in FIG. 14A, the pixel electrode 29 is formed to be in contact with the first conductive film 25dp and the third conductive film 25dr of the drain electrode 25d. Here, due to the cavity section 28a, the pixel electrode 29 is not in contact with the second conductive film 25dq. Moreover, in the auxiliary capacitor element Cs, as illustrated in FIG. 14B, the pixel electrode 29 is formed to be in contact with the first conductive film 25bp and the third conductive film 25br of the upper electrode 25b. Here, due to the cavity section 28b, the pixel electrode 29 is not in contact with the second conductive film 25bq. In the gate terminal section T_{G}, as illustrated in FIG. 14C, the pixel electrode 29 is formed to be electrically connected to the terminal 22c.

As described above, the TFT substrate 20 is fabricated. According to the method for fabricating the TFT substrate 20, the first contact hole 27a and the second contact hole 27b are formed in the first etching step. Then, in the second etching step, between the first conductive film 25dp and the third conductive film 25dr, and between the first conductive film 25bp and the third conductive film 25br, the cavity sections 28a, 28b are respectively formed in the wall of the first contact hole 27a and the wall of the second contact hole 27b, so that the second conductive films 25dq, 25bq are respectively spaced apart from the first contact hole 27a and the second contact hole 27b. The high-resistance coatings and the passivation coatings formed in the first etching step are removed in the second etching step. In the portion forming the thin film transistor T_{R}, the pixel electrode 29 formed in the pixel electrode formation step is in contact with the drain electrode 25d at the first conductive film 25dp and the third conductive film 25dr other than the second conductive film 25dq, so that the pixel electrode 29 is electrically connected to the drain electrode 25d. Thus, a contact failure between the pixel electrode 29 and the drain electrode 25d due to the high-resistance coating and the passivation coating formed on the surface of the drain electrode 25d is not caused. Thus, satisfactory contact between the pixel electrode 29 and the drain electrode 25d is achieved. Moreover, in the portion forming the auxiliary capacitor element Cs, the pixel electrode 29 formed in the pixel electrode formation step is in contact with the upper electrode 25b at the first conductive film 25bp and the third conductive film 25br other than the second conductive film 25bq, so that the pixel electrode 29 is electrically connected to the upper electrode 25b. Thus, a contact failure between the pixel electrode 29 and the upper electrode 25b due to the high-resistance coating and the passivation coating formed on the surface of the upper electrode 25b is not formed. Thus, satisfactory contact between the pixel electrode 29 and the upper electrode 25b is achieved.

The TFT substrate 20 fabricated by the above-described method and the counter substrate 30 including pixels each provided with a color filter are arranged to face each other and are adhered to each other by the sealing material 40, and a liquid crystal material is filled between the substrates, thereby forming the liquid crystal layer 50, so that the liquid crystal display device 10 can be obtained.

Although it has been described that the resist is removed by oxygen ashing in the first etching step, the resist may be removed by, for example, a resist remover solution, etc. When the resist is removed by using a resist remover solution, the aluminum film is not oxidized, and surfaces of the second conductive films 25dq, 25bp are not covered with aluminum oxide films, that is, with passivation coatings. However, due to the etching step, the surfaces of the second conductive films 25dq, 25bp are covered with high-resistance coatings made of aluminum fluoride, and thus there is a problem where a contact failure may be caused even when the second conductive films 25dq, 25bp are brought into contact with the pixel electrode 29. In contrast, according to the thin film transistor substrate having a configuration of the present embodiment, the first contact hole 27a, and the second contact hole 27b are formed in the first etching step, and then in the second etching step, between the first conductive film 25dp and the third conductive film 25dr and between the first conductive film 25bp and the third conductive film 25br, the cavity sections 28a, 28b are respectively formed in the wall of the first contact hole 27a and the wall of the second contact hole 27b so that the second conductive films 25dq, 25bq are respectively spaced apart from the first contact hole 27a and the second contact hole 27b. Thus, the high-resistance coatings formed in the first etching step is removed in the second etching step. Thus, satisfactory contact can be achieved without a contact failure between the pixel electrode 29 and the drain electrode 25d and between the pixel electrode 29 and the upper electrode 25b caused due to the existence of the high-resistance coating on the surface of the drain electrode 25d.

### INDUSTRIAL APPLICABILITY

The present invention is useful for thin film transistor substrates and liquid crystal display devices including the thin film transistor substrates, as well as for the thin film transistor substrates.

### DESCRIPTION OF REFERENCE CHARACTERS

Cs Auxiliary Capacitor Element
T_{R} Thin Film Transistor
10 Liquid Crystal Display Device
20 Thin Film Transistor Substrate (TFT Substrate)
21 Substrate
22a Gate Electrode
22b Lower Electrode
23 Gate Insulating Film
24a Oxide Semiconductor Film
24ac Channel Section
24b Etch Stopper Layer
25a Oxide Semiconductor Film
25b Upper Electrode
25d Drain Electrode
25dp, 25bp First Conductive Film
25dq, 25bq Second Conductive Film
25dr, 25br Third Conductive Film
25s Source Electrode
26 Interlayer Insulating Film
27a First Contact Hole
27b Second Contact Hole
28a, 28b Cavity Section
29 Pixel Electrode
30 Counter Substrate
40 Sealing Material
50 Liquid Crystal Layer

1. A thin film transistor substrate comprising:
a substrate;
a thin film transistor including
a gate electrode provided on the substrate,
a gate insulating film provided to cover the gate electrode,
an oxide semiconductor film provided on the gate insulating film and including a channel section formed at a position facing the gate electrode, and
a source electrode and a drain electrode provided on the oxide semiconductor film to be spaced apart from each other with the channel section sandwiched therebetween;
an interlayer insulating film which is provided above the gate insulating film to cover the thin film transistor and in which a first contact hole extending to the drain electrode is formed;
a pixel electrode provided on the interlayer insulating film and electrically connected to the drain electrode via the first contact hole, and
an auxiliary capacitor element including
a lower electrode provided on the substrate in a same layer as the gate electrode,
the gate insulating film provided to cover the gate electrode and the lower electrode,
an etch stopper layer made of an oxide semiconductor provided on the gate insulating film at a position facing the lower electrode, and
an upper electrode provided on the etch stopper layer in a same layer as the drain electrode, wherein
the drain electrode includes a first conductive film and a second conductive film which is made of aluminum and is stacked on the first conductive film, and the second conductive film and the first contact hole are spaced apart from each other with a cavity section formed therebetween, where the cavity section is in communication with the first contact hole,
the pixel electrode is provided to be out of contact with the second conductive film of the drain electrode,
the auxiliary capacitor element is covered with the interlayer insulating film in which a second contact hole extending to the etch stopper layer and the upper electrode is further formed,
the upper electrode includes a first conductive film and a second conductive film which is made of aluminum and is stacked on the first conductive film, and the second conductive film and the second contact hole are spaced apart from each other with a cavity section formed therebetween, where the cavity section is in communication with the second contact hole, and
the pixel electrode is provided on an inner surface of the second contact hole to be electrically connected to the upper electrode without contacting the second conductive film of the upper electrode.

2. (canceled)

3. The thin film transistor substrate of claim 1, wherein
the first conductive film is made of a refractory metal film.

4. The thin film transistor substrate of claim 1, wherein
the drain electrode further includes a third conductive film provided on the second conductive film in addition to the first conductive film and the second conductive film.

5. The thin film transistor substrate of claim 4, wherein
the upper electrode further includes a third conductive film provided on the second conductive film in addition to the first conductive film and the second conductive film.

6. A liquid crystal display device comprising:
the thin film transistor substrate of claim 1;
a counter substrate disposed to face the thin film transistor substrate; and
a liquid crystal layer provided between the thin film transistor substrate and the counter substrate.

7. A method for fabricating the thin film transistor substrate of claim 1, the method comprising:
a thin film transistor formation step of forming the thin film transistor including
the gate electrode provided on the substrate, and
the gate insulating film provided to cover the gate electrode,
the oxide semiconductor film provided on the gate insulating film and including the channel section formed at a position facing the gate electrode, and
the source electrode and the drain electrode provided on the oxide semiconductor film to be spaced apart from each other with the channel section sandwiched therebetween, where each of the source electrode and the drain electrode includes the first conductive film and the second conductive film stacked on the first conductive film;
an interlayer insulating film formation step of forming the interlayer insulating film above the gate insulating film to cover the thin film transistor formed in the thin film transistor formation step;
a first etching step of performing, after the interlayer insulating film formation step, dry etching on the interlayer insulating film to form the first contact hole extending from the interlayer insulating film to the drain electrode to expose the second conductive film in the first contact hole;
a second etching step of performing wet etching on the first contact hole, which has been formed in the first etching step, by using an etchant having a high selectivity ratio with respect to an aluminum-oxide semiconductor to form a cavity section between the second conductive film and the first contact hole to allow the second conductive film to be spaced apart from the first contact hole, where the cavity section is in communication with the first contact hole; and
a pixel electrode formation step of forming, after the cavity section is formed in the second etching step, a conductive film in a region including a surface of the interlayer insulating film and an inner surface of the first contact hole to from the pixel electrode which is electrically connected to the drain electrode without contacting the second conductive film of the drain electrode, wherein
the etchant used in the second step is ammonia water.

8. (canceled)

9. The thin film transistor substrate of claim 1, wherein
the oxide semiconductor film is made of an In—Ga—Zn—O-based film.

10. The method of claim 7, wherein
the oxide semiconductor film is made of an In—Ga—Zn—O-based film.
